(19) United States
(12) Patent Application Publication
(10) Pub. No.: US 2003/0218474 A1
(43) Pub. Date: Nov. 27, 2003

(54) Wafer testing apparatus

(76) Inventor: Masaru Sanada, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/445,553

(22) Filed: May 27, 2003

(30) Foreign Application Priority Data
May 27, 2002 (JP) 153053/2002

(51) Int. Cl. H01L 21/66; H01L 23/58

(52) U.S. Cl. 324/765; 257/48; 438/18; 324/754

(57) ABSTRACT

A wafer testing apparatus for testing or burn-in testing a large number of LSIs formed on a wafer to be tested in a lump according to the present invention includes a base for placing the wafer to be tested; a film having a metal pattern for covering and connecting the wafer to be tested; a depressing means for contacting the metal pattern on the film to an optional electrode portion on the surface of the wafer to be tested, and depressing and fixing the film on the wafer to be tested; and a conducting means, which is a terminal on the base for conducting wirings on the wafer to be tested to wirings on the film.

### BACKGROUND OF THE INVENTION

1. Field of the Invention

The present invention relates to a wafer testing apparatus, and more specifically to a wafer burn-in testing system for detecting defective products of large-item, small-number LSIs.

2. Description of the Prior Art

First, a tester environment which is the background for enabling wafer burn-in will be described. First, the trend of the testing system that improves the wafer testing will be described.

As FIG. 22A shows, a conventional testing system is a system referred to as the stored testing system wherein a test pattern in inputted from an LSI tester 40 through an input pad of an LSI 11b of a circuit to be tested 42, and the output results are taken out through the output pad of the LSI to the LSI tester 40 to compare with the anticipated value in the LSI tester 40. The LSI tester 40 consists of a test-pattern generating circuit 41 and a test judgment circuit 43.

Whereas, as FIG. 22B shows, the recent test is performed by a testing system, for example, referred to as the BIST (built-in self test) that incorporates a test-pattern

generating circuit 41 and a test judgment circuit 43 in an LSI chip 11c, using a simplified function LSI tester 40a. Namely, the advantage of this testing system is that in an LSI having a large number of pads, the test can be conducted using a small number of input/output pins, and furthermore, even in the tester having a small number of functions, a slow clock input can operate at a high speed by adding a harmonic generation function as the testing circuit, as if a high-end tester is used.

Here, the BIST will be described. In the BIST, a pseudo-random number pattern generating circuit known as LFSR (linear feedback shift resister) inputs a pattern in an optional circuit, the pattern is compressed the logic outputted from MISR (multiple input signature register), and the outputted logic is compared with the anticipated value to judge the function of the operating circuit. In this case, the number of pins used in the LFSR is only a pin for testing the clock signal, and the signal outputted form the MISR can also tested using only one pin. Furthermore, when a higher test is conducted, by handling an order circuit block referred to as SCAN as if a combined circuit, the functions to simplify the internal operation, and to input an optional logic in a desired combined circuit can be added.

By applying such simple tests corresponding to the purposes to the testing system for wafer burn-in, the feasibility of the wafer burn-in test, which was difficult using conventional methods, can be seen. Furthermore, when the object of the wafer burn-in test is considered, burn-in chiefly operates the interior of an LSI at a desired temperature (normally 125 to 150° C. as the joint temperature in the LSI), and the flow to take out the sample at an optional time to measure using a tester is effective.

Namely, the specifications not to monitor the output values in the logic operation by burn-in may be possible. As a result, no complicated testing apparatuses are required. Furthermore, a simplified testing apparatus shown below enables the burn-in test for large item small volume production by lump probing of an entire wafer. As described above, it is important that change in the test environment enables the use of small pins in the hardware.

Furthermore, the purpose of wafer burn-in is a technique for selecting defective LSIs including initial failure in a wafer level, and that no monitoring of the anticipated output value is required during burn-in.

There are largely two problems in prior art. One is the burn-in apparatus, and the other is the contact sheet for burn-in in the wafer level. There are two purposes in the burn-in test in the LSI test. FIG. 23 is a graph that shows a bathtub curve for illustrating the purposes. The first of the purposes is the selection for eliminating defective products including initial defect at the time of shipment shown in the point A in FIG. 23; and the other is the monitoring of degradation in a high-temperature accelerating state from the viewpoint of reliability shown in the point B in FIG. 23. The technique addressed by the present invention is the former.

Conventionally, in both the two above-described tests, the burn-in tests were conducted by selecting LSIs to fabricate a chip into a package, inserting the packaged product in a board, placing the board in a high temperature vessel, and connecting the board terminal to the tester. The difference between the two was the testing time, and the details of the test were substantially the same. Namely, the internal logic operation was performed by inputting a pattern for the functional test for fully selecting the LSIs into an inputting terminal; taking out the board from the high temperature vessel every anytime; and electrical properties were measured using a tester to determine the non-defective and defective of the LSIs.

Thereafter, to solve the problem described later, the wafer burn-in test has been conducted. The wafer burn-in test is the burn-in test conducted in the state of the wafer after completing the above-described LSI manufacturing process. The conventional wafer burn-in test is the testing system in the state using all the pads in the LSI.

First, there is a constitution described in Japanese Patent Application Laid-Open No. 6-140483 (prior art example 2). In this constitution, a wafer to be tested whereon LSIs are arranged is placed on a base; an ultra-high-density anisotropic conductive film is laid over the wafer to be tested; a wafer for selection is laid thereon; and these wafers are conducted through an elastic conducting member assisted by a depressing member. The signals and power source on the wafer to be tested are extracted from the bonding pads in the LSI through the edge connectors on the elastic conducting member. Namely, optional pads on the wafer to be tested are conducted to the pad portions on the wafer to be tested through the ultra-high-density anisotropic conductive film; the electrode is extracted from the opening provided on the opposite surface of the wafer for selection, and connected to a metal pillar in the elastic conducting member on the wafer to be selected; and the terminal is extracted through the elastic conducting member, and connected to the edge connector. It is characterized that the same number and the same arrangement of terminals as the terminals of LSIs on the wafer to be selected as described as “the contact terminals are in the same arrangement pattern as the arrangement pattern of the terminals of the LIS.” Furthermore, the terminals that can be used in common are set up and terminated in the same wiring.

Next, there is also the constitution shown in Japanese Patent Application Laid-pen No. 10-321686 (prior art example 3). This constitution has the function to control the temperature of the wafer to be tested whereon LSIs are arranged; fixed on the wafer supporting table having an elevating/lowering mechanism; and a probe guard to be a flexible multi-layer wiring board formed from polyimide is fixed thereon so as to seal the space of the cover portion. The wafer to be tested is connected to the probe card by introducing a fluid into the sealed portion. The fluid is also used for controlling the temperature. Conductive bumps are formed on the lower surface of the probe card, and are arranged so as to correspond to all the pads of all the LSIs in the wafer to be tested. Electrodes to external devices are connected through the conductive paths in the cover portion from the bump contacts on the cover portion contacting the end of the probe card.

Since the conductive bumps provided on the probe card must correspond to all the pads of all the LSIs in the wafer to be tested, there is a problem that a probe card must be prepared for each kind of LSIs having difference in size, pad location, and pad arrangement.

Although the contact of the probe card to the wafer to be tested is adjusted by introducing a fluid into the sealed space in the cover portion that fix the probe card, since the probe card is a solid, such as polyimide, there are problems that the contact by the expansion thereof cannot be realized unless the pressure of the fluid is elevated; and furthermore, a perfect sealing must be realized. Therefore, the probe card itself had a problem that a highly accurate card that produces no voids in the entire card including the connecting hole to the lower surface had to be used. Together with these technical problems, there are also the problems of increase in the costs. Furthermore, there is a problem that cannot correspond to large item small volume production.

Furthermore, in what is described in Japanese Patent Application Laid-Open No. 7-115113 (prior art example 4), in order to test the LSI on the wafer to be tested, the testing substrate is contacted to the wafer to be tested through an anisotropic conductive film, and conduction between pads is achieved by depressing and fixing them. The testing substrate is a silicon substrate having a coefficient of thermal expansion as large as 13×10⁻⁶/° C. or below, and an electric circuit required for the test is formed thereon. Furthermore, the wafer to be tested is fixed to the stage by evacuation.

The structure (prior art example 5) fixed a probe composed of a wiring board for connecting electrodes on a large number of pads on the wafer to be tested called a TPS (three parts structure) probe, an anisotropic conductive rubber, and a thin polyimide film with bumps on the wafer to be tested.

This method intends that fluctuation due to thermal expansion is controlled by using a wiring board and a thin polyimide film with bumps, the cushioning properties to absorb the fluctuation of the heights of bumps formed on the wafer are enhanced by using an anisotropic conductive rubber, and the contact between the TPS and the wafer to be tested is improved by even depression by atmospheric pressure by hermetically sealing between the wafer tray and the wiring board.

Furthermore, the following has been proposed concerning the contact sheet for the burn-in in the wafer level. That is, in Japanese Patent Application Laid-Open No. 10-284556 (prior art example 6), the contact sheet is a porous-material-based sheet made of a fluorine-containing polymer-based polymer. Furthermore, the polymer is based on a fluorinated ethylene/propylene wherein an adhesive is inserted. These polymers are porous material having 30 to 70% initial void volume, containing a filler and an additive such as polyester and polyethylene. The contact sheet has through-holes filled with a conductive metal between a plurality of polymers for supplying signals from the wafer to be tested and power source. Furthermore, the above-described sheets are combined to form a three-layer structure.

The above-described prior art had problems described below. First, the burn-in test of a packaged LSI as a burn-in device had a problem that the LSI determined as normal in the test conducted in the normal conditions would be found to be defective in the burn-in process, and the man-power, time, and the costs until packaging were wasted. Furthermore, there was a problem that the number is limited in the burn-in test of packages, and 100% test could not be conducted.

Although there was a wafer burn-in test system (prior art example 2) for solving these problems, since the wafer to be tested is connected to the wafer for the test through an anisotropic conductive film, there was a problem that a high pressure had to added to depress these three members.

The communication of all signals and power source to the LSI was made by the figuration connected to external devices through an elastic conductive member and through electrodes in the wafer for selection, and furthermore, since the pads on the wafer for selection had to be established in the same location as the pad portions on the wafer to be tested, the large item small volume production wherein a wafer for selection had to be prepared each time the layout of the LSI changed resulting in high costs. Also since elastic conductive members for the connection of signals and power source had to be formed on the wafer for the test, there was a problem that the structure of the main body to conduct wafer burn-in was complicated.

Also in the prior art example 3, since the conductive bumps formed on the probe card must correspond to all the pad portions of all the LSIs in the wafer to be tested, there is a problem that a probe card must be prepared each time the type of the products changes due to difference in the size of the LSIs, locations and arrangement of the pads.

Although the contact between the probe card and the wafer to be tested was controlled by introducing a fluid into the sealed space in the cover portion for fixing the probe card, since the probe card was a solid, such as polyimide, there was a problem that the contact by the expansion of the fluid unless the pressure of the fluid is elevated, and that a perfect sealing had to be realized. Therefore, the probe card itself had a problem that a highly accurate card that did not produce voids in the entire card including the holes connected to the lower surface had to be used. These had a technical problem as well as a problem of high costs. There was also a problem that the system could not deal with large item small volume production.

Also, although the structure of prior art example 4 enabled self test by superposing the wafer for the test on the wafer incorporating a testing circuit called the testing substrate, there was a problem that the elements on the testing substrate were also degraded at an accelerating pace and several-time use is difficult because the entire system are driven at a high temperature, and since the facility for evacuating from the opening of the wafer stage was required to planarize the wafer for the test, there was a problem to apply the system to wafer burn-in.

Since the pads of the testing substrate having a testing circuit had been prepared on the locations corresponding to the pads of the LSI on the wafer to be tested, and since a testing substrate had to be prepared each time the LSI size and pad locations changed, there was a problem that it is difficult to apply the system to large item small volume production in the viewpoint of the costs. Furthermore, although the power supply from an external device to the testing substrate is not described herein, the power supply is difficult in the proposed figuration.

In the case of prior art example 5, although electrode were connected to a large number of pads on the wafer for testing using a TPS probe constituted from a wiring board, an anisotropic conductive rubber, and a thin polyimide film with bumps, there was a problem that the TPS probe itself was a large system, and consumed a high costs.

Furthermore, as in prior art example 4, since the contact portions of the TPS probe had to correspond to the locations of the pads on the wafer for testing, there was a problem that a TPS probe depending on the size of the LSI had to be prepared each time the size of the LSI on the wafer for testing changed, and the system was difficult to apply to large item small volume production. The common point in these systems is that the four prior art examples required large equipment, and although the object thereof was the reduction of costs and man-hour by selecting defective products in upstream processes, there was a problem that the testing substrate and the wafer for extracting and testing signals from each LSI on the wafer for testing had to have a structure depending on the layout of the product.

In addition, in the case of the contact sheet for burn-in in prior art example 6, since the polymer used in this case was based on fluoro-polymers, there was a problem that even the composite polymer wherein various additives such as polyester, polystyrene, and filler were mixed has a coefficient of thermal expansion five to ten times the coefficient of thermal expansion of the silicon wafer.

Furthermore, since the contact sheet had a composite structure using an adhesive, there was danger to generate an organic gas in the high-temperature atmosphere during burn-in, and to contaminate the LSI. Furthermore, in the screening apparatus using this contact sheet had a mechanical depression mechanism, since a conductive Z-axis member was placed under the above-described composite polymer, a laminated contact sheet was placed thereunder, and contacted to the wafer to be tested, there was a problem that a complicated mechanism was required to complement the buffering causing the costs to elevate.

### BRIEF SUMMARY OF THE INVENTION

Summary of the Invention

A wafer testing apparatus for testing or burn-in testing a large number of LSIs formed on a wafer to be tested in a lump according to the present invention includes a base for placing the wafer to be tested; a film having a metal pattern for covering and connecting the wafer to be tested; a depressing means for contacting the metal pattern on the film to an optional electrode portion on the surface of the wafer to be tested, and depressing and fixing the film on the wafer to be tested; and a conducting means, which is a terminal on the base for conducting wirings on the wafer to be tested to wirings on the film.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a sectional view showing a wafer testing apparatus according to an embodiment of the present invention;

FIGS. 2A and 2B are sectional views showing the constitution of the wafer testing apparatus shown in FIG. 1 partially disassembled and assembled again, respectively;

FIG. 3A is a top view of the wafer to be tested 10 shown in FIG. 1; and FIG. 3B is a partially enlarged view thereof;

FIG. 4 is a top view of the wafer to be tested 10 shown in FIG. 1, whereon an input/output circuit is formed;

FIG. 5A is a sectional view showing the wiring structure of the wafer to be tested 10 shown in FIG. 1; and FIG. 5B is a partially enlarged view thereof;

FIG. 6A is another sectional view showing the wiring structure of the wafer to be tested 10 shown in FIG. 1; and FIG. 6B is a partially enlarged view thereof;

FIG. 7 is a top view of an ordinary LSI wherein pads are formed in a region to constitute electric circuit elements;

FIGS. 8A, 8B and 8C are a perspective view, a sectional view, and a partially enlarged sectional view of a film wired facing the wafer to be tested 10 shown in FIG. 1, respectively;

FIGS. 9A and 9B are a top view and a sectional view of another film wired facing the wafer to be tested 10 shown in FIG. 1, respectively;

FIGS. 10A and 10B are a top view and a sectional view of still another film wired facing the wafer to be tested 10 shown in FIG. 1, respectively;

FIG. 11 is a top view of yet another film wired facing the wafer to be tested 10 shown in FIG. 1;

FIGS. 12A, 12B and 12C are a perspective view, a sectional view, and a partially enlarged sectional view of another film wired facing the wafer to be tested 10 shown in FIG. 1, respectively;

FIGS. 13A and 13B are a front view and a back view of a film shown in FIG. 1, respectively;

FIGS. 14A and 14B are a front view and a back view of another film shown in FIG. 1, respectively;

FIGS. 15A, 15B and 15C are top views of three metal bosses corresponding to the pads of the wafer shown in FIG. 1;

FIG. 16 is a sectional view showing the state wherein a thin metal wire is used on a film 3 shown in FIG. 1;

FIGS. 17A and 17B are sectional views showing a manufacturing method wherein a thin metal wire is used on a film 3 shown in FIG. 1;

FIG. 18 is a sectional view showing another manufacturing method wherein a thin metal wire is used on a film 3 shown in FIG. 1;

FIGS. 19A and 19B are sectional views showing the members of the wafer testing apparatus according to the second embodiment of the present invention, disassembled and assembled again, respectively;

FIGS. 20A and 20B are a sectional view and a partially enlarged sectional view showing the state wherein depressions are formed between through-holes underneath the film shown in FIG. 1, respectively;

FIG. 21 is a top view showing a structure of the film 3 shown in FIG. 1 whereon slits are formed;

FIGS. 22A and 22B are block diagrams for illustrating a stored testing system and a BITS system, which are conventional LSI testing system; and

FIG. 23 is a graph for illustrating the failure rate of general products, and showing a bath-tub curve that takes the failure rate on the ordinate and time on the abscissa.

### DETAILED DESCRIPTION OF THE PREFERRED EMBODIMENTS

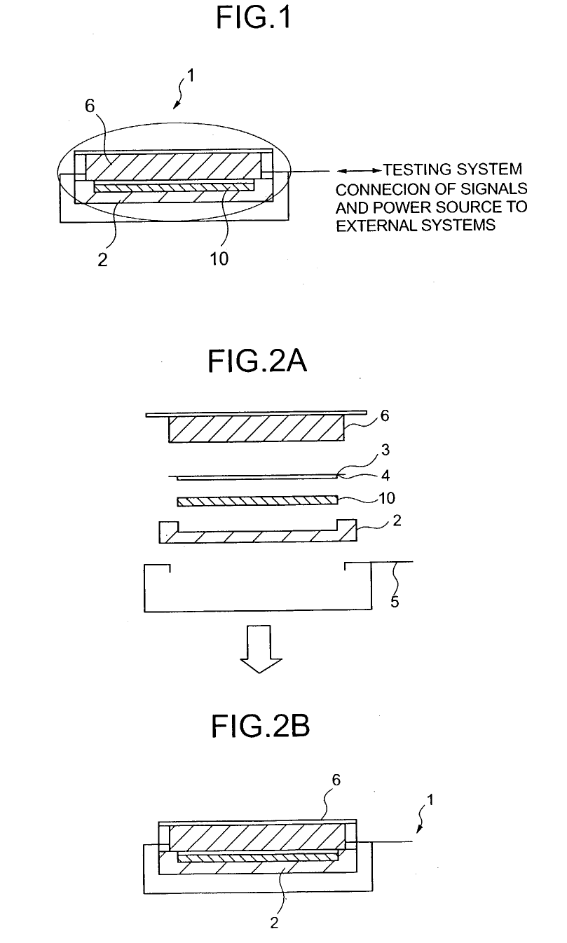

The embodiments of the present invention will be described below referring to the drawings. FIG. 1 is a constitution diagram showing a wafer testing apparatus according to an embodiment of the present invention; FIGS. 2A and 2B are sectional views showing the constitution of the wafer testing apparatus shown in FIG. 1 partially disassembled and assembled again, respectively. The wafer testing apparatus is composed of a wafer board system 1 that places a wafer to be tested 10, set up the environment such as temperature, and takes out signals; a measuring system for performing signal connection and power source connection with the wafer board system 1; and a testing system (not shown) consisting of a parameter-processing system.

The wafer board system 1 has a circuit constitution having the above-described environment for testing a large number of LSIs 11 formed on the wafer to be tested 10. In other words, the wafer board system 1 has a constitution wherein a film 3 having a metal pattern 4 is placed on a wafer to be tested 10 placed on a base 2, and the optional electrode portion on the surface of the wafer to be tested 10 is contacted to the metal pattern 4 on the film 3 by depressing the wafer to be tested 10 and the film 3 with a depressing plate 6 from the above. The depressing means 5 has, for example a depressing bag that is expanded by introducing a fluid like a balloon.

FIG. 2A shows a disassembled view of the wafer board system 1. The wafer board system 1 has the constitution wherein a wafer to be tested 10 is placed on the base 2, a film 3 having a wiring (metal) pattern 4 is placed on the wafer to be tested 10, and when these are depressed with the depressing plate 6, required signals and electrode wirings are extracted from an external lead wiring 5 provided on the base 2, and are connected to external systems through terminals ending at the base 2.

Although it is not shown, a burn-in test can also be conducted by controlling temperature from the bottom of the base 2, or placing the whole apparatus described above in a constant-temperature bath. The combination of the above-described constitutions is shown in FIG. 2B.

The LSI that realizes the above-described test environment has a figuration that easily realizes the wafer test by providing signal wirings on the scribe line (15) on the wafer 10 to bring in the power-source electrode from the source other than the wafer, that is, by supplying the power-source electrode from the sides of the base 2 whereon a wafer to be tested 10 is placed, or the film 3.

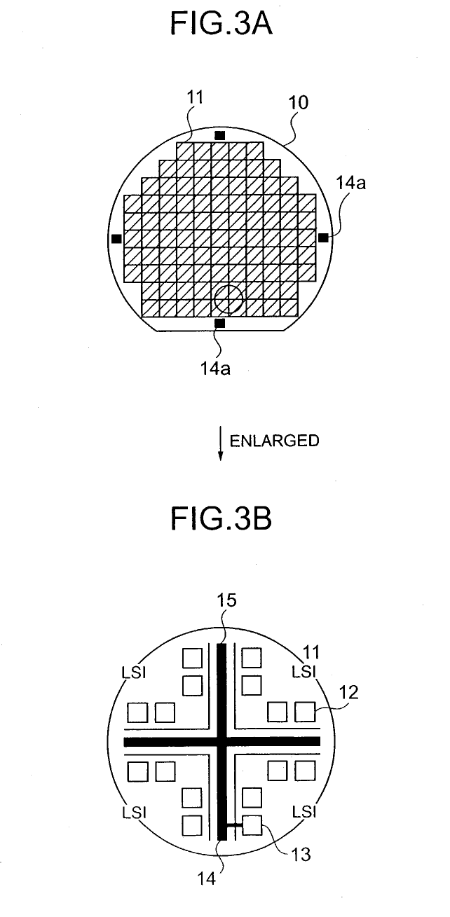

First, a wafer to be tested 10 used in the wafer testing apparatus will be described. The constitution of the wafer to be tested 10 that realizes the above-described test environment equipped with the circuit and layout whereto the testing function is imparted will be described. The first is shown in the top view and partially enlarged view of the wafer 10 in FIGS. 3A and 3B. Namely, as FIG. 3A shows, a large number of LSIs 11 are installed on the wafer 10, and clock-signal terminals 14a are formed on the several locations thereof. As FIG. 3B shows, each LSI 11 is characterized in having pads 12 and a clock pad 13 connected to the clock-signal line 14, laying a metal wiring in the region of the scribe line 15 that separates LSIs 11 to connect to an optional input/output terminal of each LSI 11, and that the metal wiring terminates at the corner of the wafer.

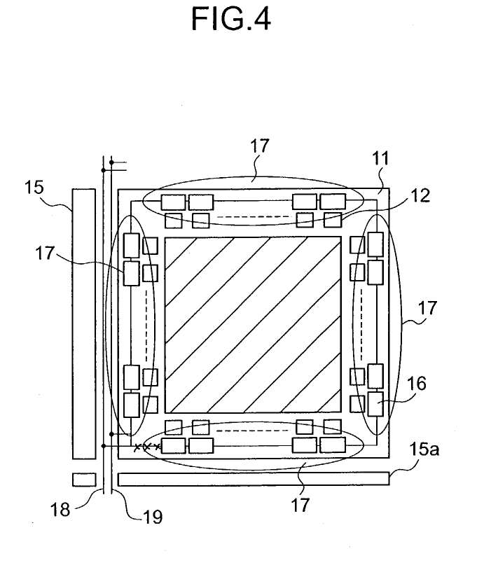

The second is shown in FIG. 4, wherein flip-flops 16 are formed between the scribe line 15 that separates LSIs 11 and input/output terminals, the flip-flops 16 are connected to corresponding input/output terminals (pads) 12, and furthermore, the metal wiring laid in the scribe line region 15 is connected to the signal terminals of the flip-flops 16. All of these flip-flops 16 are connected in each block to constitute a SCAN chain 17, and the wiring 18 of enable signals and the wiring 19 of input signals are connected to the first input of the SCAN chain 17.

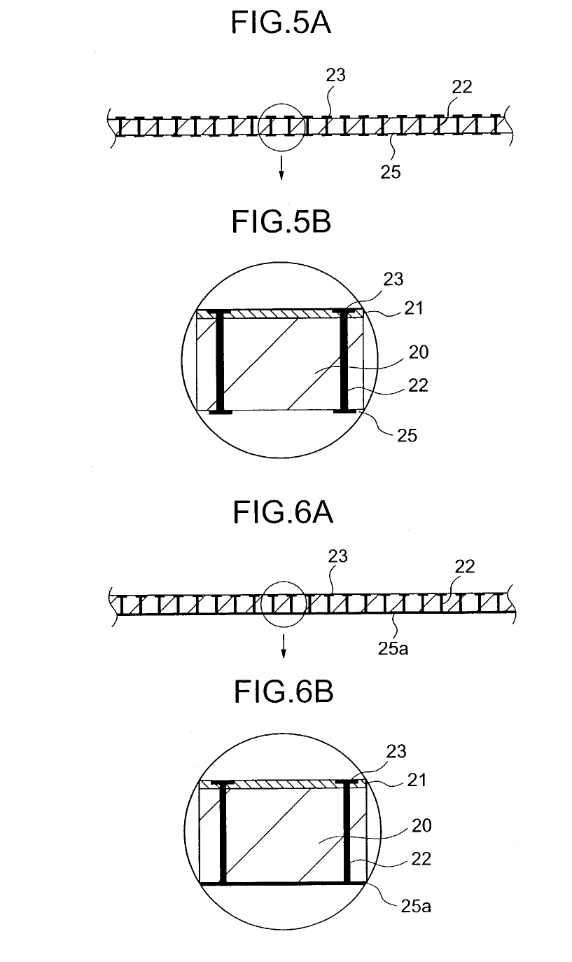

Furthermore, a sectional view and a partially enlarged view of the wiring of the wafer to be tested 10 to realized the wafer lump contact of the wafer 10 are shown in FIGS. 5A and B, respectively. In the wafer to be tested 10, through holes 22 are formed in a semiconductor (silicon) substrate 20 having an oxide film 21 formed on the surface thereof, the through holes 22 are filled with a metal, GND pads 23 are formed on the upper surface of the through holes 22, and GND electrode pads 24 to be connected to a metal pattern 25 are formed on the lower surface of the through holes 22.

A GND potential can be supplied to the wafer to be tested 10 from the base 2 whereon the wafer to be tested 10 is placed by forming through holes 22 filled with a metal in the semiconductor substrate 20 from the surfaces of low-potential-side electrode (GND) pads 24 for driving the LSI on the lower surface of the wafer whereon the LSI 11 is fabricated, and by forming metal bumps on the lower surface.

Furthermore, FIGS. 6A and 6B are a sectional view and a partially enlarged view showing other wirings of the wafer 10. In the structure shown in FIG. 6, by the constitution wherein the entire surface of the wafer to be tested 10 is covered with a metal pattern 25a, and the surface of low-potential-side electrode (GND) pads 23 are electrically connected through through-holes 22 to electrodes 24 drawn to the lower surface, a GND potential can be supplied to the wafer to be tested 10 from the base 2 as in the structure shown in FIG. 5.

This technique is feasible by forming through-holes in a silicon substrate, forming insulating films on the sides of the through-holes, and filling the through-holes with a metal. Here, as methods to form through-holes in the silicon substrate, although the technique using RIE, the laser processing technique, and the wet etching technique known as PAECE (Photo Assist Electro Chemical Etching) have been known. However, since the PAECE method can be applied only to N-type silicon, the methods that can be used for forming through-holes in a P-type wafer generally used are only the RIE technique or the laser processing technique. Furthermore, the processing time of the RIE technique to form a through-hole of a diameter of 50 μm in the depth direction is 10 μm/min, whereas the processing time of the laser processing technique to form a through-hole of a diameter of 50 μm in the depth direction is 10 μm/min. However, since the laser processing technique has a problem of contamination by the reaction products, the combination of the RIE technique and the laser processing technique is generally used.

Insulation in the through-holes can be achieved by steam oxidation. However, the through-holes in this embodiment conduct a lowest potential to a P-type substrate, no insulation is required. The through-holes can be filled with metals, such as indium, tin, and solder, using a known molten metal suction method.

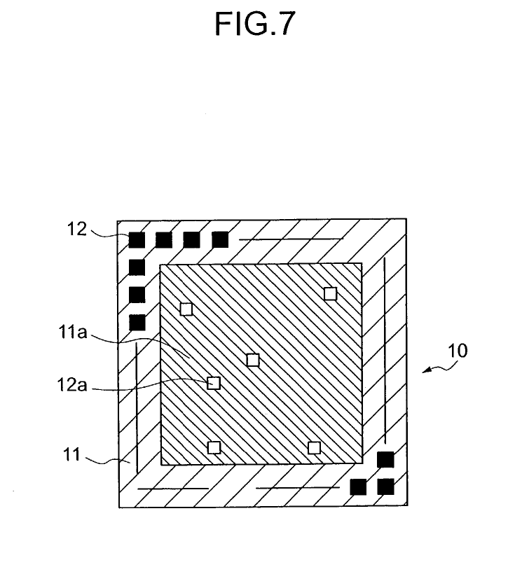

FIG. 7 is a top view showing the layout of a normal LSI 11 on a wafer 10. In the LSI 11, normal pads 12 are arranged on the circumference of the active region 11a thereof, and pads for the test 12a are arranged on the active region 11a. Signals are supplied to such pads for the test 12a from the film 3.

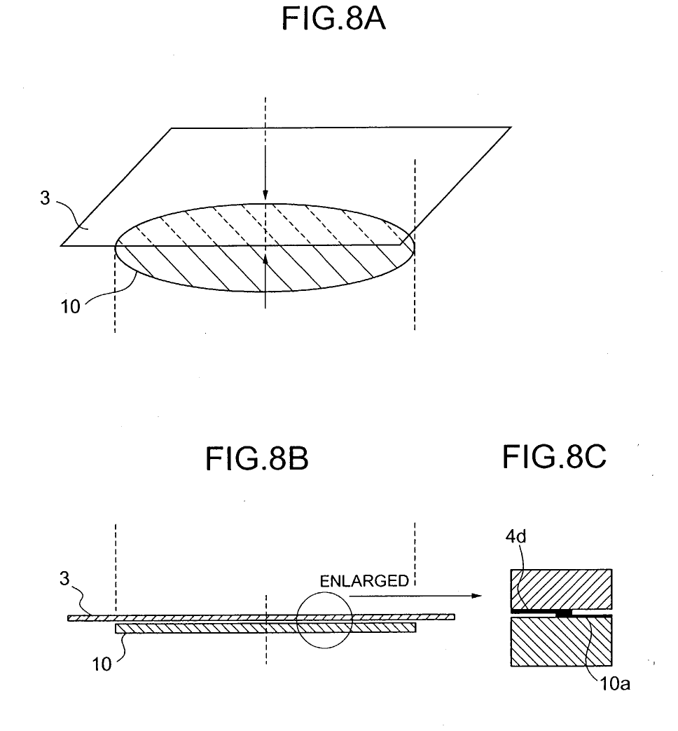

There are two conformations in the films 3 in this embodiment. One is a conformation having a metal pattern 4 on the surface of the film 3 of the side facing the wafer to be tested 10; and the other is a conformation having a metal pattern 4 on the surface of the film 3 opposite to the side facing the wafer to be tested 10. First, the case wherein a metal pattern is formed on the surface of the film 3 facing the wafer to be tested 10 will be described. This test is feasible by contacting the wafer to be tested 10 to the film having wiring on the surface facing the wafer to be tested 10 as shown in FIG. 8.

FIGS. 8A to 8C are perspective view, a sectional view, and a partially enlarged view of the state wherein the wafer to be tested 10 is contacted to the film 3 having wirings on the surface facing the surface of the wafer to be tested 10, and a metal pattern 4 is formed on the surface of the film 3 facing the surface of the wafer to be tested 10, respectively. As FIGS. 8A and 8B show, the wafer to be tested 10 is contacted to the film 3; and as FIG. 8C shows, the wiring 10a on the wafer to be tested 10 is contacted to the wiring 4d underneath the film 3 through the metal projection of the film 3.

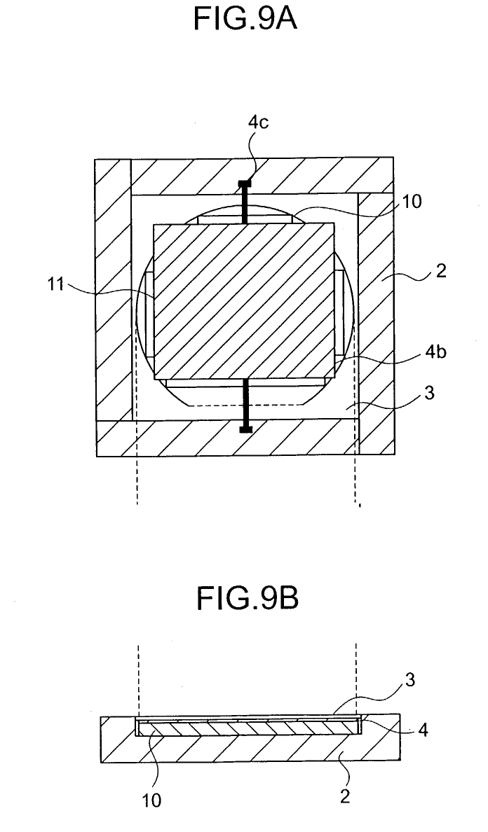

In the above-described electrode supply, the power from the side of the film 3 when a GND electrode is formed on the side of the base 2 is only VDD, which is the highest potential. Therefore, the metal pattern 4 on the surface of the film 3 may be a metal pattern 4b whose surface is composed of an equal-potential layout pattern, as FIG. 8 shows. FIG. 9A is a top view of a figuration wherein the film 3 is overlaid on the LSI 11 placed on the base 2, and the metal pattern 4b, that is the equal-potential pattern composed of a single pattern, is situated on the lower surface of the film 3. FIG. 9B is a sectional view thereof. Furthermore, although it is not shown, the ends 4c of the metal pattern are situated on the base 2, and connected to the terminal of the base 2.

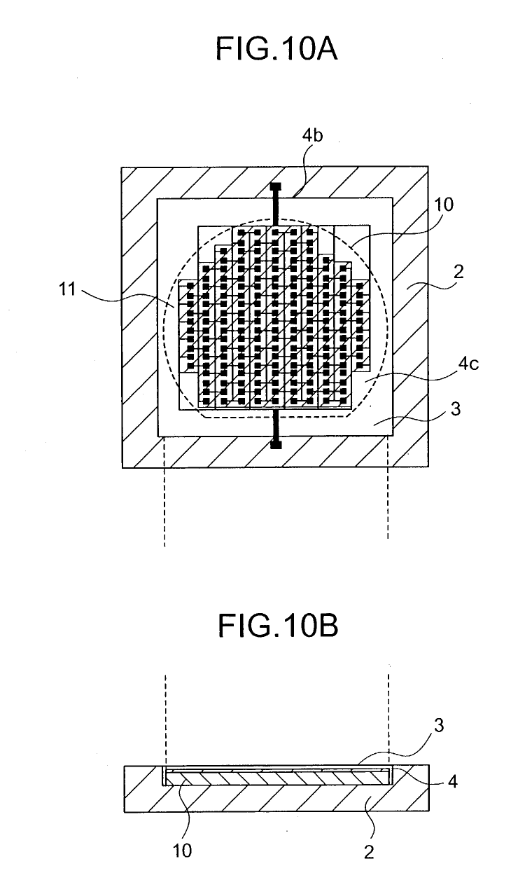

In the metal pattern on the surface of the film when the supply of two electrodes (VDD, GND) performed from the film, as FIG. 10 shows, the metal patterns 4a can be constituted in one layer by disposing the metal patterns 4d connected to the VDD pad side and the GND pad side on the wafer in a comb shape, and by disposing on each pad. FIG. 10A is a top view of the state wherein the LSI placed on the base is covered with the film 3, and the metal pattern 4e divided into two portions, which becomes the equal-potential pattern (30) for supplying two electrodes (VDD, GND), is situated on the back of the film. FIG. 10B is a sectional view showing this state. Furthermore, although it is not shown, the end 4c of the metal pattern is situated on the base 2, and is connected to the terminal of the base 2. Here, the supply of electrodes is described; however, the arrangement and the pattern figuration apply to the supply of a plurality of signals.

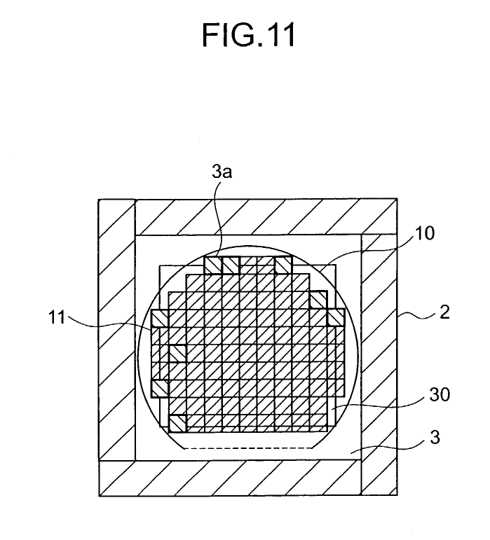

Next, the method for forming an opening in the film so that the LSI determined as defective in P/W is not subjected to the burn-in test will be described. Basically, by not supplying one power source, the test is not conducted. In one method, as the arrangement diagram of FIG. 11 shows, on the location of optional LSIs 11 that constitute the wafer to be tested 10 covered by the film 3 having the wiring of the equal-potential pattern 30 (metal pattern 4e), openings 3a of the same or like size as the LSI 11 are provided; and in the other method, although it is not shown, openings 3a are provided in the circumference including the pad portions 12 of optional LSIs 11 that constitute the wafer to be tested 10 covered by the film 3.

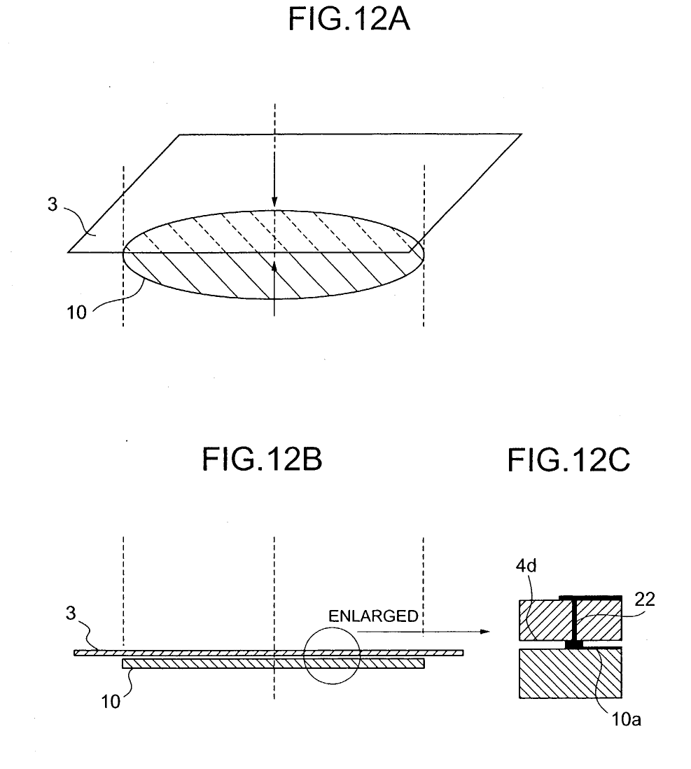

Next, the case wherein metal patterns are formed on the opposite film surface facing to the surface of the wafer to be tested 10 will be described. The test in this case is, as shown in FIG. 12, feasible by contacting the wafer to be tested 10 to the metal boss 7 formed on the back through a through-hole 22 of the film 3 having wirings on the opposite film surface facing to the surface of the wafer to be tested 10. FIGS. 12A to 12C are a perspective view, a sectional view, and a partially enlarged view of the combination thereof, respectively.

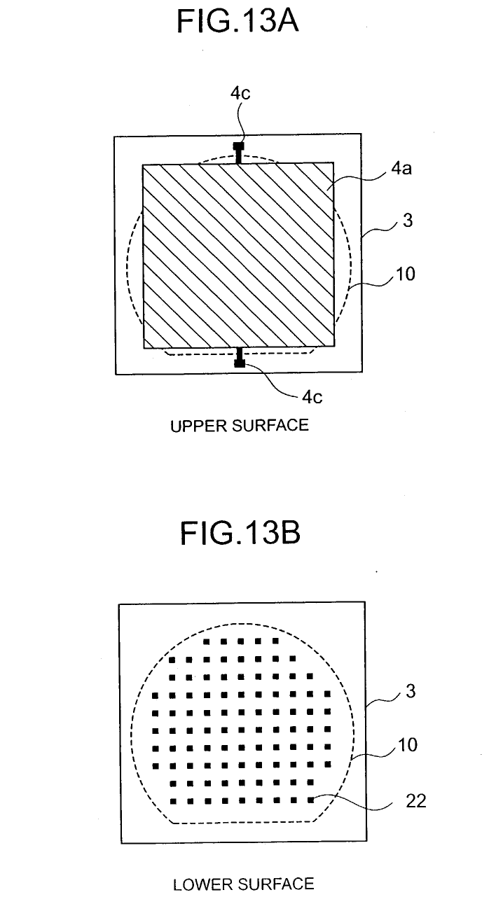

The metal pattern 4 on the surface of the film 3 is connected to the metal boss 7 on the back through the through-hole 22. The location of the metal boss 7 is a location that contacts an optional electrode portion on the wafer to be tested 10. In the above-described electrode supply, when the GND electrode is formed on the base 2 side, the power source from the film 3 side is only VDD, which is the highest potential. Therefore, as FIG. 13 shows, the metal pattern on the film surface may be a metal pattern 4a one of whose surface is composed of an equal-potential layout pattern. FIG. 13A is a top view of the figuration of an LSI placed on the base (not shown) covered with a film 3, and the metal pattern 4a that becomes an equal-potential pattern composed of a single pattern is situated on the surface of the film 3. FIG. 13B is a bottom view of the film showing a metal boss 7 on the location corresponding to the corresponding GND pad on the wafer to be tested 10. The ends 4c of the electrode pattern are formed on the corners of the surface of the film, and are connected to the terminals of the base.

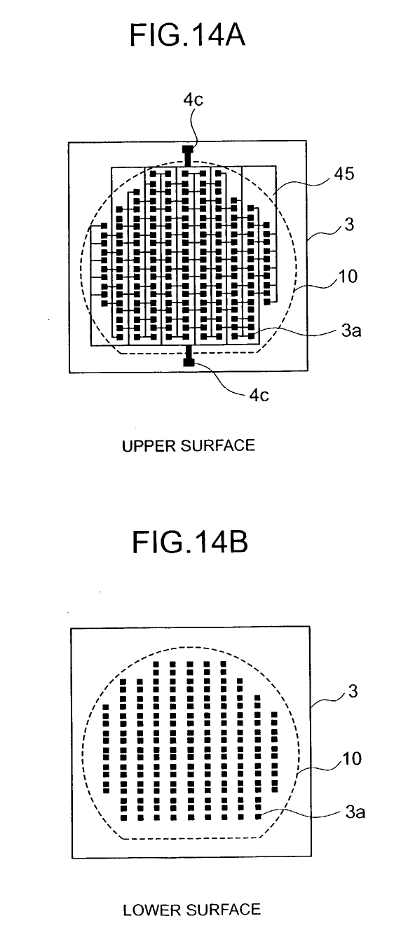

In the metal pattern on the surface of the film when the supply of two electrodes (VDD, GND) performed from the film 3, as FIG. 14 shows, the metal patterns 4f can be constituted in one layer by disposing the metal patterns 4d connected to the VDD pad side and the GND pad side on the wafer 10 in a comb shape, and by disposing on the surface portion through a through-hole 3a of the metal boss 7 situated on each pad 12. FIG. 14A is a top view of the figuration wherein the LSI 11 placed on the base (not shown) is covered with a film, and the metal patterns 4f, which is an equal-potential pattern for supplying two electrodes (VDD, GND), is formed on the surface of the film. FIG. 14B is a bottom view of the film, and shows metal bosses 7 on the locations corresponding to two corresponding electrode pads 12 on the wafer to be tested 10. The ends 4c of the electrode pattern are formed on the corners of the film surface, and are connected to the terminals of the base. Furthermore, although not shown in the drawing, the ends of the electrode pattern are situated on the base, and are connected to the terminals of the base. Here, the supply of the electrodes is described; however, the arrangement and the pattern figuration apply to the supply of a plurality of signals.

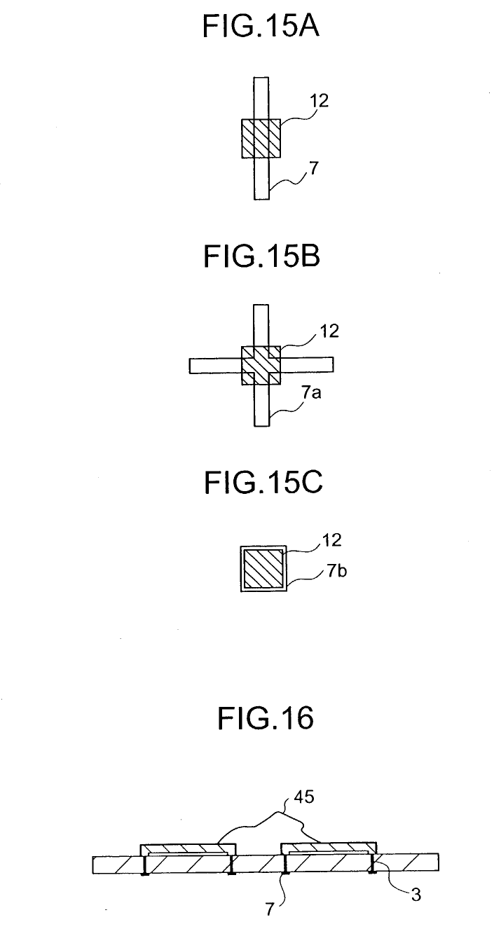

Next, the shape of metal bosses 7 of the film 3 will be described. The metal bosses 7 of the film 3 have a size longer than a side of an optional pad portion 12 of each LSI 11 that composes the wafer to be tested 10 covered with the film 3. FIG. 15A shows a metal boss 7 extending in a side direction, and FIG. 15B shows a metal boss 7a extending in a cross direction. Furthermore, as FIG. 15C shows, the metal boss 7b has a size larger than an optional pad portion 12 of each LSI 11 that composes the wafer to be tested 10 covered with the film 3. The shape of the above metal boss 7 enables the contact between the film 3 and the wafer to be tested 10 by supplementing disagreement between locations to correspond caused at a high temperature due to difference in the coefficients of thermal expansion between the film and the wafer to be tested. Furthermore, the complete supplement of contact can be enabled by enlarging the size of this shape from the center portion of the wafer outward.

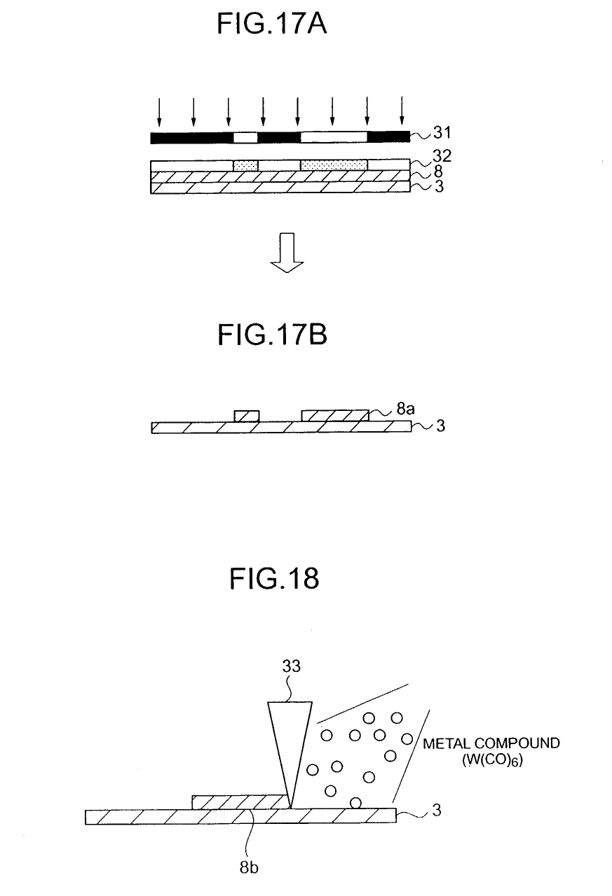

Next, the metal patterns 4 on the film 3 will be described. One can be feasible, as the top view of FIG. 16 shows, by connecting thin metal wires 4g by wiring covered with an insulating film on the surface of the film 3 on the through-holes 3a filled with a metal. The other is the system using a photo-etching technique as FIG. 17 shows. Namely, a desired metal pattern 8a can be formed by depositing a thin metal film 8 of a thickness of about 5 to 10 μm on the film 3, which is an insulator; applying a photoresist 32 thereon; radiating light through a patterned photo mask 31 (FIG. 17A); and etching off the portions other than the exposed portion (FIG. 17B).

Furthermore, as FIG. 18 shows, using known laser or ion beams 33, a metal pattern 8b can be formed by using a metal CVD (chemical vapor deposition) technique using an organic metal compound gas such as tungsten carbonyl (W(CO)₆). Furthermore, the combined use of these techniques enables the formation of a metal pattern having a plurality of wiring width and wiring film thickness.

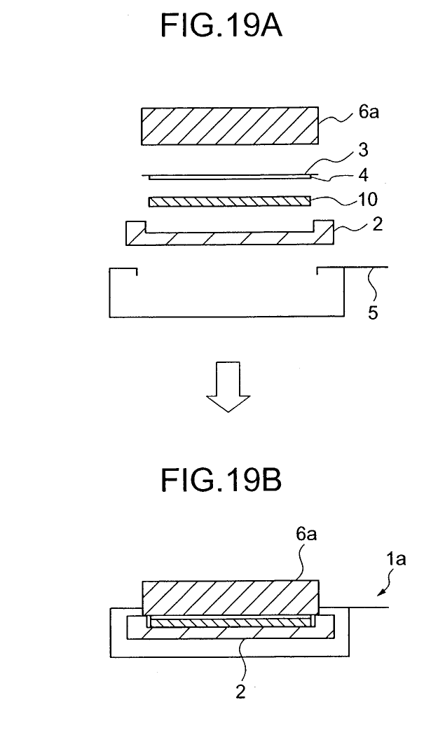

Furthermore, one of the depression systems for the wafer to be tested 10 and the film 3 is a system for depressing by controlling the pressure on the fixed metal fitting 6a consisting of a flat metal plated fixed to the substrate to overlay on the film 3 as FIGS. 19A and 19B show. FIGS. 19A and 19B show the constituents and the constitution diagram of the device to be depressed.

The other is a system for depressing by supplying a fluid in a bag so as to cover the entire portion where the surface of the wafer to be tested overlaps the surface of the film on the back of the flat plate fixed to the substrate overlapping the film as FIG. 2 shows (the supply tube is omitted in the drawings). The fluid to be supplied to the bag on the back of the flat plate overlapping the film may be a gas or a liquid. Furthermore, the fluid controlled to an optional temperature can be supplied.

It is also desirable that the material of the film 3 of this embodiment is a polymer having a coefficient of thermal expansion of about 3×10⁻⁶/K, the same as the coefficient of thermal expansion of the wafer to be tested 10 The polymer is a fibrous polymer, which is preferably a composite polymer produced by mixing a thermosetting or thermoplastic substance with a cellulose-based polymer having a coefficient of thermal expansion lower than the coefficient of thermal expansion of a polymer consisting of carbon chains. The example includes Electrolytic Capacitor Paper Type MER3.

The coefficient of thermal expansion can be controlled by allowing a filler or an insulating metal to intervene in the porous spaces. Furthermore, to control fibrous duct, all the fibers on the surface of the fibrous polymer film can be oriented to the lateral direction by using abrasives and chemical etching. The surface of the fibrous polymer film may be coated with a thin polyimide film.

Furthermore, the thickness of the film 3 is about 100 to 1,500 μm so as to flexibly respond to the depression, for example, by a pneumatic pressure. For controlling the flexibility and the coefficient of thermal expansion of the film 3, the effect is enhanced through the structure wherein the film is sliced to have a thickness of about 50 to 100 μm, and a plurality of these base materials are laminated. The flexibility and the coefficient of thermal expansion of the film 3 can also be controlled by laminating strips cut to have a width of 100 to 1,500 μm in the vertical direction to constitute a plane; or by laminating strips cut to have a width of 100 to 1,500 μm and a length of 100 to 1,500 μm in the vertical direction to constitute a plane. Such film structures are effective to control the expansion of the film in the lateral direction, because the film is composed of laterally cut strips combined in the vertical direction.

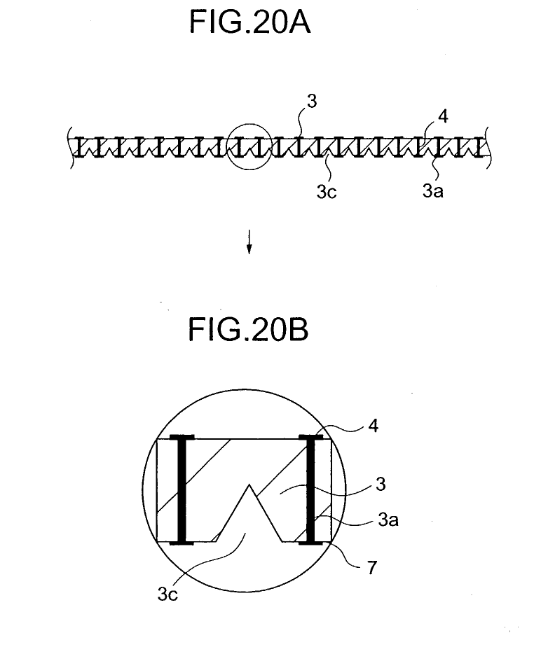

In order to solve the disagreement of the wafer to be tested 10 with the film 3 due to the difference of coefficients of thermal expansion, as FIGS. 20A and 20B show, dents 3c may be formed between the through-holes 3a on the lower surface of the film 3. This is because the disagreement at the contact location can be absorbed in the dents starting from the contact location when the expansion of the film 3 due to heat is large.

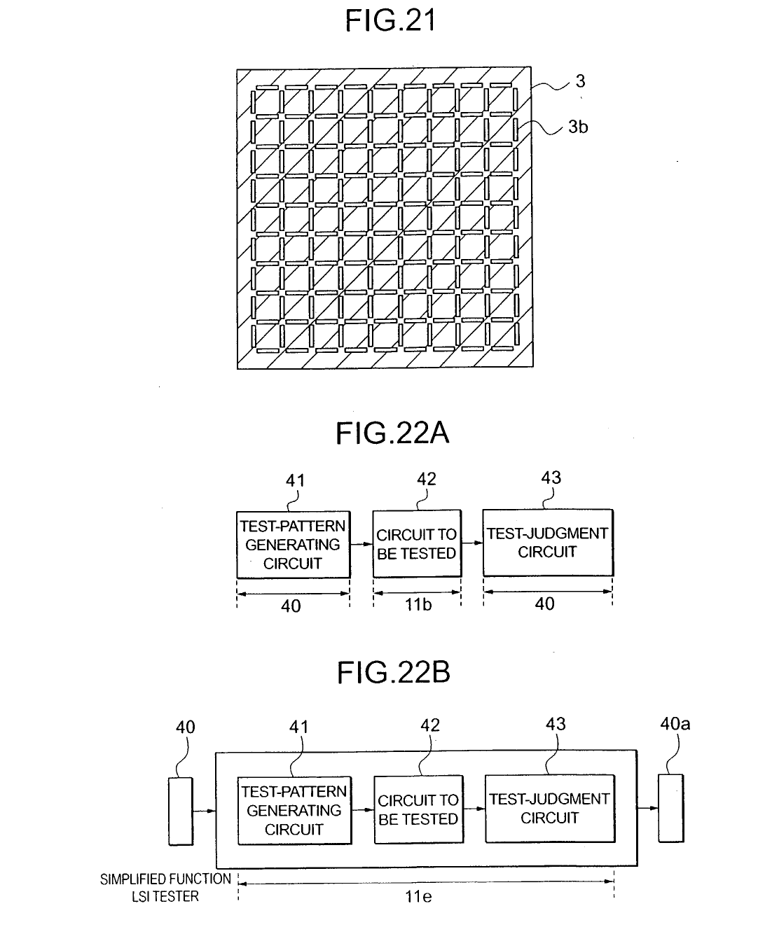

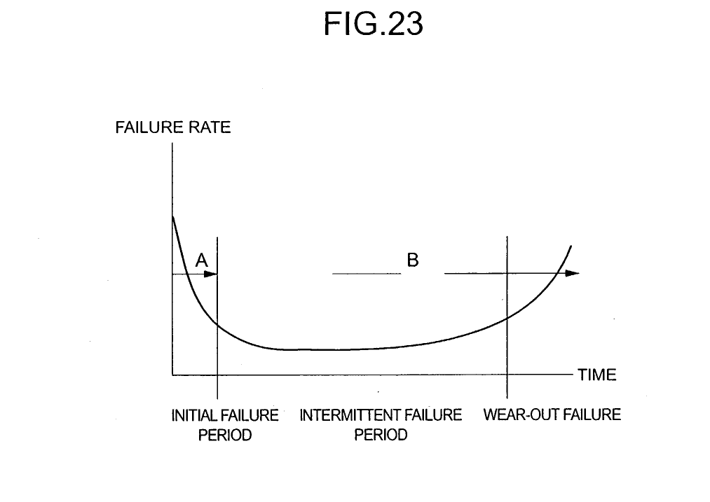

Since the formation of slits 3b formed on the film 3 as FIG. 21 shows also absorbs disagreement, the disagreement of the entire film can be eliminated. Furthermore, the structure wherein a film having a positive coefficient of thermal expansion is laid over a film having a negative coefficient of thermal expansion also solves the problem of the disagreement of the entire film by the effect of mutual cancellation of disagreement. Furthermore, these films are characterized in having a combined structure of the above-described two figurations.

Since the film structure has dents between metal bosses on the lower surface of the film, the disagreement of contact location of even a film having a large coefficient of thermal expansion from the silicon wafer caused by heat can be absorbed; and the disagreement of contact location of even a member having a large coefficient of thermal expansion from the silicon wafer caused by heat can be eliminated by slits or the combination of two kinds of materials of different coefficients of thermal expansion.

Next, the system for extracting the electrodes will be described. The extraction of signals and electrodes are performed by the structure to terminate in the terminals on the base. Namely, the signal wiring formed on the scribe line of the wafer to be tested is terminated at the corner portion, and connected to the electrode terminal of the base portion. The metal pattern on the film is terminated at the corner portion, connected to the electrode terminal of the base portion, and the electrodes are externally extracted from the external terminal of the base portion.

Next, a heating method for burn-in maintains the entire wafer to be tested 10 on the metal base 2 at an optional temperature by supplying heat from the bottom of the base 2; or the means for supplying heat from the bottom of the metal base 2 supplies heat generated by electric resistance. Alternatively, the means for supplying heat from the bottom of the metal base 2 supplies heat by blowing a hot air of an optional temperature from the bottom of the base. The entire wafer to be tested on the base can also be maintained at an optional temperature by placing the entire wafer-testing apparatus in an optional constant temperature bath.

According to the constitution of the present invention as described above, a large effect to conduct the test of products of large item small volume production easily at low costs, only by overlapping a film having a fewest required wiring to a wafer to be tested, and by depressing from the top thereof with a simple pressure, especially with a gas to contact to the power source.

First, since the system supplies power from the film on the back and surface of the wafer to be tested, and signal lines are formed on the scribe line of the wafer to be tested, the members that depends on the kinds of materials becomes a film; and since the film depends only on the locations of the through-holes, only few man-hour is required, and the constitution becomes effective for large item small volume production. Furthermore, although the testing circuit in the LSI requires a certain area, since what determines the LSI area in a multi-pin LSI is the pin arrangement, the area of the testing circuit does not affect the total area at all. Furthermore, the flip-flop circuit formed between pads and scribe lines cause no problem on the area of the region to prevent defects due to cracking in the chip in the normal design rule; therefore, the structure having an internal testing circuit does not require the overhead of the LSIs.

The film used in the present invention has the effects wherein since the metal pattern on the film can be patterned in a mono-layer structure, the wiring structure on the film simplifies the constitution of the film; since the wiring width and film pressure of the metal pattern on the film can be optional, the difference in LSIs used can be flexibly dealt with; and the metal pattern on the film can be constituted using wirings coated with insulating films, the metal pattern can be easily constituted. The film also has the effect of easily selecting LSIs whose testing is not desired, by forming openings in optional locations on the film.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A wafer testing apparatus for testing or burn-in testing a large number of LSIs formed on a wafer to be tested in a lump, comprising:
a base for placing said wafer to be tested; a film having a metal pattern for covering and connecting said wafer to be tested; a depressing means for contacting the metal pattern on said film to an optional electrode portion on the surface of said wafer to be tested, and depressing and fixing said film on said wafer to be tested; and a conducting means, which is a terminal on said base for conducting wirings on said wafer to be tested to wirings on said film.

2. The wafer testing apparatus according to claim 1, wherein said film having a metal pattern contacts with the metal pattern formed on the surface of the film facing the surface of said wafer to an optional electrode portion on said wafer.

3. The wafer testing apparatus according to claim 1, wherein said film having a metal pattern has metal bosses formed on the back of the metal pattern, and said metal bosses contact with optional electrode portions on said wafer.

4. The wafer testing apparatus according to claim 2 or 3, wherein said metal pattern on the surface of the film is constituted from an equipotential layout pattern.

5. The wafer testing apparatus according to claim 2 or 3, wherein said metal pattern on the surface of the film is constituted between optional pads from an equipotential layout pattern.

6. The wafer testing apparatus according to claim 2 or 3, wherein said metal pattern on the surface of the film is constituted from two separate patterns.

7. The wafer testing apparatus according to claim 2 or 3, wherein said film has an opening of the size equal or nearly equal to the size of a specific LSI location determined as defective in said wafer, and has an opening in the circumference including the pad portions of said specific LSI.

8. The wafer testing apparatus according to claim 2 or 3, wherein the base material of said film consists of a cellulose-based fibrous polymer, or a composite polymer formed by blending thermosetting and thermoplastic materials; the pilous glands on the surface of the fibrous polymer film is oriented; and the surface of said fibrous polymer film is covered with a thin film of a polyimide.

9. The wafer testing apparatus according to claim 1, wherein said depressing means on said film depresses a flat metal plate fixed on a substrate to overlap said film by controlling the pressure with a screw.

10. The wafer testing apparatus according to claim 1, wherein said depressing means on said film is depressed by gaseous or liquid fluid supplied to a bag covering the entire overlap portion of the wafer face and the film to the rear face portion of a flat panel fixed to the substrate superposed on the film.

11. The wafer testing apparatus according to claim 10, wherein the temperature of the wafer is controlled by said fluid controlled to a predetermined temperature.

12. The wafer testing apparatus according to claim 1, wherein means whereby the terminal on the base conducts to the wiring on the wafer and the wiring on the film connects to said the terminal on the base by connecting the wiring terminated at the corner of said wafer and said base electrode portion and the wiring terminated at the corner of said film and said base electrode portion.

13. The wafer testing apparatus according to claim 1, wherein the heat supply means for maintaining the wafer at a predetermined temperature is supplied with heat from the underside of the base so as to maintain the entire wafer on said base at the predetermined temperature.

14. The wafer testing apparatus according to claim 13, wherein said heat supply means is heated through electric resistance.

15. The wafer testing apparatus according to claim 1, wherein the heat supply means for maintaining the wafer at a predetermined temperature makes the entire wafer on the base at the predetermined temperature by placing the entire wafer test device in any thermostatic chamber.
